(19) United States
(12) Patent Application Publication
(10) Pub. No.: US 2025/0102537 A1
(43) Pub. Date: Mar. 27, 2025

(54) Process for Manufacturing an Electric Current Sensor by Additive Manufacturing

(71) Applicants: Commissariat à l'Energie Atomique et aux Energies Alternatives, Paris (FR); LEACH INTERNATIONAL EUROPE SAS, Sarralbe (FR)

(72) Inventors: Manuel FENDLER, Grenoble (FR); Maxime FRANCK, Sarralbe (FR); Tanguy LACONDEMINE, Grenoble (FR)

(73) Assignees: Commissariat à l'Energie Atomique et aux Energies Alternatives, Paris (FR); LEACH INTERNATIONAL EUROPE SAS, Sarralbe (FR)

(21) Appl. No.: 18/898,962

(22) Filed: Sep. 27, 2024

(30) Foreign Application Priority Data
Sep. 27, 2023 (FR) 2310267

(51) Int. Cl. G01R 1/04; B33Y 10/00; B33Y 80/00; G01R 1/20

(52) U.S. Cl. CPC G01R 1/0416; G01R 1/203; B33Y 10/00; B33Y 80/00

(57) ABSTRACT

The invention relates to a method for manufacturing an electric current sensor (SHE) comprising the following steps:
a) providing a metal or metal alloy substrate (SBT),
b) making a non-through cavity (CVT) in said substrate so that said cavity separates the substrate into two areas (Z1, Z2),
c) producing a resistive element (ER) in said cavity (CVT) by additive manufacturing,
d) annealing the resulting assembly,
e) removing a part of the substrate (SBT) to leave only the resistive element (ER) between the two areas (Z1, Z2) of the substrate, and
f) defining, within each area (Z1, Z2), a connection terminal (BCE1, BCE2) to obtain electrodes (PEL, DEL).

### TECHNICAL FIELD OF THE INVENTION

The invention relates to the field of manufacturing electrical current sensors, for example an electrical shunt.

### TECHNICAL BACKGROUND

A known electrical shunt is shown in FIG. 1.

Typically, an electrical measurement shunt 1 consists of a calibrated resistive element 2, electrodes 3, 3′, electrical connection terminals 4, 4′ and measurement terminals 5, 5′ defined on the electrodes 3, 3′ respectively. The electrical connection terminals 4, 4′ allow an electrical current to flow under the effect of a potential difference (voltage), which may be measured between the measurement terminals 5, 5′. By means of the calibrated value of the resistance of the resistive element 2 and the voltage measurement at the measurement terminals, it is possible to deduce the electrical current flowing through the electrical measurement shunt 1, using the Ohm's law.

The calibration of the resistive element 2 is generally achieved by localized machining of the resistive element. For example, reference may be made to WO 2017/065144 A1 wherein it is proposed to make notches in the resistive element 2 while it is supplied with electricity, in order to adjust the value of its resistance (in-situ calibration, during measurement). Alternatively, the resistive element 2 may also be calibrated by mechanical adjustment when the electrical shunt 1 is fitted, by geometrically controlling the contact surface between two resistive elements. This is for example what is proposed in WO 2019/190144 A1 or WO 02/56320 A1.

The resistive element 2 is generally made of a copper-based alloy. The copper-based materials used for the resistive element 2 typically have resistivities of between 20 and 50 μΩ·cm, and temperature coefficients of resistance (variation in resistivity as a function of the temperature) of up to ±30·10⁻⁶·K⁻¹. The composition of these alloys (copper, manganese, nickel, tin, iron and silicon) gives them electrical characteristics that guarantee accurate, reliable measurement over an operating temperature range from 0° C. to 175° C. Reference may be made, for example, to WO 2022/044611 A1 or WO 2022/030071 A1.

In addition, the resistive element 2 is usually brazed to the electrodes 3, 3′ with Silver 6, 6′. This assembling by silver brazing limits its use to certain materials. The electrodes 3, 3′ are therefore mainly made of copper or a copper-based alloy. It should be noted that the assembly of the resistive element 2 with the electrodes 3, 3′ has been the subject of numerous publications. Examples comprise WO 2011/068205 A1, WO 2017/110354 A1 and WO 2015/080333 A1.

The assembly of the electrical connection terminals 4, 4′ to the electrodes 3, 3′ has also been the subject of publications. In particular, WO 2019/097924 A1, WO2019/097925 A1 and KR10-2016-0101251 may be cited, comprising proposals for reducing or eliminating the contact resistance between the electrical connection terminals and the electrodes. There are many ways of assembling the various elements of the electrical measurement shunt, comprising pressure bonding, brazing, welding (electrical resistance, laser, electron beam) and metal casting. Each assembly method must be compatible with the materials (resistive element, electrode and measurement terminal), ensure a good electrical conductivity between the assembled elements (minimize contact resistance), and guarantee the mechanical strength of the electrical measurement shunt assembly.

It should also be noted that the geometries and dimensions of the resistive elements have an influence on the thermal and electrical behavior of the electrical measurement shunts.

There are solid bar shapes, shapes based on a multitude of thin bars (WO 2017/065144 A1, WO 2019/190144A1, CN209231398U), or rod or tube shapes (WO 2018/150870 A1, WO 2013/005824 A1, WO 2011/068205 A1). In particular, the tube shape allows to limit the Joule effect losses by taking advantage of the skin effect when alternating currents flow.

In all cases, the materials used for the resistive elements are selected on the basis of their electrical properties (resistivity and temperature coefficient of resistance), which determines the choice of electrode materials, most of which are copper-based. The resistive element and the electrodes must be able to be assembled and have compatible electrical and thermal properties, not to mention the contact resistance induced between the various elements of the measurement shunt.

The manufacturing methods (assembly and calibration techniques) are also factors that limit the geometric and dimensional optimization of the electrical measurement shunts. The contact areas between the resistive element, the electrodes, the connection and measurement terminals must all be accessible to allow an assembly by brazing, welding or molding. Machining the resistive element for performing the calibration is an additional post-fabrication step.

One objective of the invention is to propose a method for manufacturing an electric current sensor that does not have at least one of the aforementioned disadvantages.

### SUMMARY OF THE INVENTION

To meet this objective, the invention proposes a method for manufacturing an electric current sensor comprising the following steps:
a) providing a metal or metal alloy substrate,
b) making a non-through cavity in said substrate so that said cavity separates the substrate into two areas,
c) producing a resistive element in said cavity by additive manufacturing,
d) annealing the resulting assembly,
e) removing a part of the substrate to leave only the resistive element between the two areas of the substrate, and
f) defining, within each area, a connection terminal to obtain electrodes.

The method according to the invention may comprise at least one of the following additional steps, taken alone or in combination:
the substrate provided in step a) is made of Aluminum, Copper or a Copper-based alloy;
the cavity produced in step b) is obtained by machining the substrate;
step c) is carried out by cold spraying, advantageously at a pressure of less than 15 bar;
step d) is performed at a temperature of between 400 and 600° C. for a period of between 5 and 15 minutes;
the method comprises an additional step consisting in making a measurement terminal in each of the two electrodes;
the resistive element does not undergo any machining step, in particular to adapt the value of its resistivity;
the substrate provided in step a) is a solid cylinder;
the substrate provided in step a) is a solid parallelepiped;
the sensor is an electrical shunt.

### BRIEF DESCRIPTION OF THE FIGURES

Further objects and characteristics of the invention will become clearer in the following description, made with reference to the attached figures, wherein:

FIG. 2 represents a hollow cylindrical electrical shunt obtained by the manufacturing method according to the invention;

FIG. 3 shows a method for manufacturing the electrical shunt shown in FIG. 2;

FIG. 4a is a diagram showing an installation for implementing a low-pressure cold spray additive manufacturing method;

FIG. 4b is a diagram showing an installation for implementing a high-pressure cold spray additive manufacturing method;

FIG. 5a represents a substrate that may be used to start the manufacturing method according to the invention;

FIG. 5b represents the substrate of FIG. 5a after being machined;

FIG. 5c represents the assembly formed after deposition by additive manufacturing of a resistive element in a non-through orifice in the machined substrate of FIG. 5d;

FIG. 5d represents the electrical shunt finally obtained after annealing and drilling through the assembly of FIG. 5c;

FIG. 6 represents the electrical shunt after adding measurement terminals;

FIG. 7 shown is a busbar-type electrical shunt obtained using the manufacturing method according to the invention.

### DETAILED DESCRIPTION OF THE INVENTION

The following description is based on the case where the electrical current sensor is an electrical shunt. However, the invention is not limited to the manufacture of an electrical shunt.

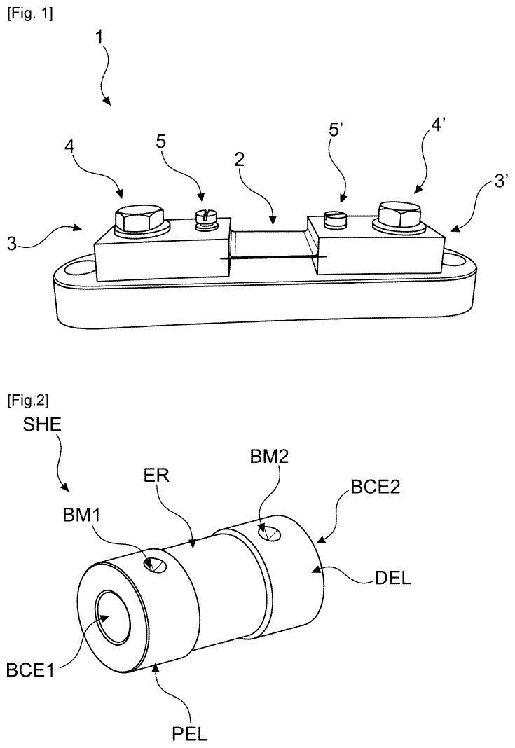

FIG. 2 is an example of embodiment of an electrical shunt SHE, in this case of hollow cylindrical shape, obtained using the method described in the invention.

The electrical shunt SHE comprises a first electrode PEL, a second electrode DEL and a resistive element ER between the two electrodes PEL, DEL. Each electrode PEL comprises an associated connection terminal BCE1, BCE2 respectively located at the ends of the electrical shunt. A measurement terminal BM1, BM2 is also provided on each electrode PEL, DEL. In this embodiment, both the electrodes PEL and LED and the resistive element form hollow cylinders.

FIG. 3 shows schematically the various steps in the method for manufacturing an electrical current sensor such as an electrical shunt SHE, in particular the one shown in FIG. 2:
a) providing a metal or metal alloy substrate SBT,
b) making a non-through cavity CVT in said substrate so that said cavity separates the substrate into two areas Z1, Z2,
c) producing a resistive element ER in said cavity CVT by additive manufacturing,
d) annealing the assembly thus obtained at the end of step c),
e) removing a part of the substrate SBT to leave only the resistive element ER between the two areas Z1, Z2 of the substrate, and
f) defining, within each area Z1, Z2, a connection terminal BCE1, BCE2 for obtaining said electrodes PEL, DEL.

The substrate SBT supplied in step a) may be made of Aluminum, Copper or a Copper-based alloy and more generally of any electrically conductive metal or metal alloy. By using an additive manufacturing step, the method according to the invention allows a wider range of metals or metal alloys to be used, while limiting the contact resistances between the resistive element ER and the electrodes PEL, DEL. In particular, it is possible to use aluminum, which has the advantage of being much lighter than copper-based alloys. This may be important for certain applications.

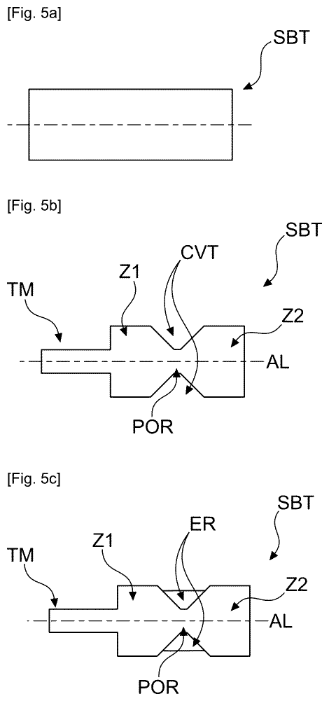

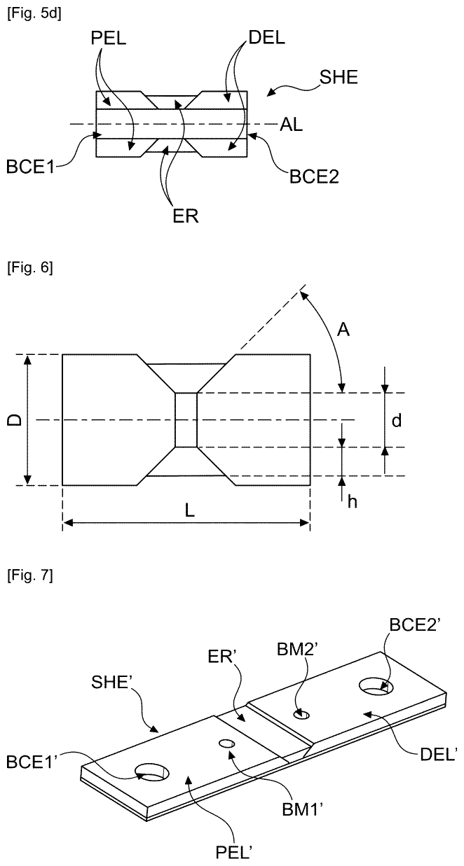

The substrate supplied in step a) is shown in FIG. 5a. This is a solid cylinder.

The non-through cavity CVT produced in step b) is obtained, for example, by machining the substrate SBT. This is particularly the case when a solid cylindrical substrate is provided in step a), from which material is then removed to obtain the desired final shape of the electrical shunt SHE. As the cavity CVT does not pass through, there remains at this stage a portion POR of substrate connecting two areas Z1, Z2 of this same substrate located on either side of the cavity CVT.

According to an alternative embodiment, steps a) and b) may be merged by additively manufacturing the substrate SBT to the desired shape. This may be done by a method referred to as “cold spray”, or by a method referred to as “direct energy deposition”.

At the end of step b), a substrate as defined in FIG. 5b) is obtained. As may be seen in this figure, the substrate in this case comprises a retaining rod TM which is only useful for manipulating the substrate SBT during certain steps of the manufacturing method. This retaining rod TM is configured to disappear during the rest of the manufacturing method.

Various additive manufacturing techniques may be used to implement step c).

The “Cold Spray” method may also be used to advantage. The “Cold Spray” method (also referred to as “Gas Dynamic Spraying” or “Kinetic Spraying Process”) is a coating deposition method based on the supersonic spraying of solid powder at a temperature below the melting point of the materials forming the powder grains. It is the kinetic energy acquired by the grains of powder that allows them to plastically deform the materials of which they are composed in order to ensure the adhesion of the deposit. The temperatures involved in this method are lower than those involved in other thermal spraying methods.

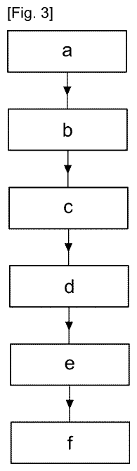

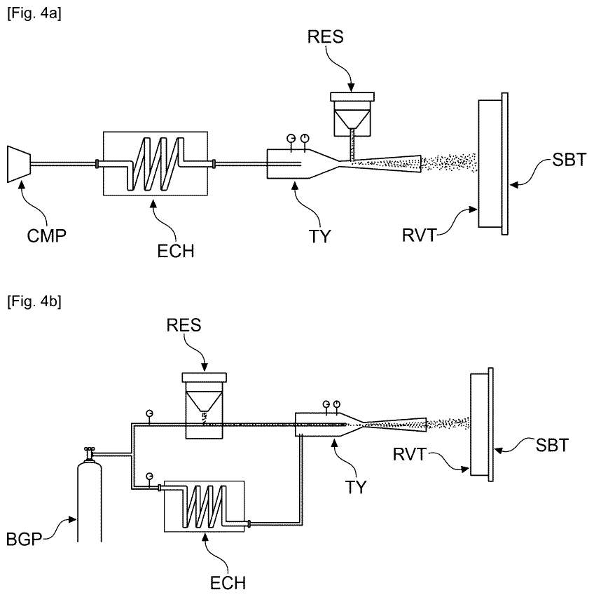

FIG. 4a shows an installation for implementing a “Cold Spray” deposition method, operating at low pressure (better referred by the acronym LPCS for “Low Pressure Cold Spray”).

More specifically, the installation comprises a compressor CMP allowing to inject a carrier gas, for example air or nitrogen, into a heater or heat exchanger ECH. The exiting gas is thus pressurized, typically to pressures below 15 bar (low pressure) and under temperature, typically below 1000° C. and in any case below the melting temperature of the material forming the powder grains, before entering a nozzle TY, typically a Laval nozzle. The nozzle TY expands the previously heated and pressurized gas, accelerating the speed of the gas jet and making it supersonic. A powder reservoir RES is used to inject powder into the nozzle TY, for example downstream of the nozzle neck, with grains of selected material. At the nozzle outlet, the powder is sprayed against a substrate SBT to deposit a coating RVT, which may be in the form of one or more successive layers. In addition, the or each layer of coating deposited may be deposited in different ways, for example in a spiral, in rings of different diameters or following parallel generatrixes, etc. Typically, particles of between 5 and 50 μm may be sprayed at speeds of around 600 m/s. The LPCS is generally used for spraying “soft” materials. The sprayed material in powder form may be mixed with alumina (also in powder form) to increase the yield and density of the deposit.

With regard to the LPCS, for example, see the article by Shuo Yin, Pasquale Cavaliere, Barry Aldwell, Richard Jenkins, Hanlin Liao, Wenya Li, Rocco Lupoi, “Cold spray additive manufacturing and repair: Fundamentals and applications”, Additive Manufacturing, Volume 21, 2018, Pages 628-650, ISSN 2214-8604, https://doi.org/10.1016/j.addma.2018.04.017.

FIG. 4b shows another installation for implementing a “Cold Spray” deposition method, operating at high pressure (better referred by the acronym HPCS for “High Pressure Cold Spray”).

More specifically, the installation comprises a pressurized gas cylinder BGP for injecting a carrier gas, for example air, nitrogen or helium, into two parallel circuits, one comprising a heater or heat exchanger ECH, the other comprising a powder tank RES arranged to inject the powder into the circuit concerned. The two circuits are then combined before entering a nozzle TY, for example a Laval nozzle. The gas from the circuits is thus pressurized, typically to pressures in excess of 15 bar (high pressure) and under temperature, which in this case may exceed 1000° C. while remaining at a temperature below the melting point of the material forming the powder grains, before entering the nozzle TY. The nozzle TY expands the previously heated and pressurized gas, accelerating the speed of the gas jet and making it supersonic. On leaving the nozzle TY, the powder is sprayed against a substrate SBT to deposit a coating RVT, which may be in the form of one or more successive layers. In addition, the or each layer of coating RVT deposited may be deposited in different ways, for example in a spiral, in rings of different diameters or following parallel generatrixes, etc. Typically, particles of between 5 and 50 μm may be sprayed at speeds of up to 1000 m/s. The HPCS is generally used for spraying “hard” materials such as titanium. For the applications covered by the invention, it is advantageous to implement a LPCS (low pressure) cold spray, typically between 4 and 10 bar and more particularly between 4 and 8 bar, with a powder particle size of between 5 and 25 μm. It is also advantageous to deposit this powder at a temperature of between 400° C. and 600° C. The carrier gas used to project the powder against the substrate, such as air, is particularly suitable.

The material making up the powder and therefore the resistive element ER may be a metal, for example Copper, Nickel, Aluminum or Zinc, or a copper-based metal alloy, for example Manganin, Noventin, Zeranin or Constantan. In practice, the use of Manganin, with a particle size of between 5 and 25 μm, is particularly well suited to the applications covered by the invention, in particular for the electrical shunt SHE shown in FIG. 2. In particular, this Manganin may then be co-projected with alumina (advantageously with a particle size less than or equal to 25 μm to increase the yield and the density of the deposit. In the case of co-projection, the quantity of alumina, which is not zero, may represent up to 40% by mass of the alumina+manganin powder mixture. The increase in yield means that the ratio between the quantity of material deposited and the quantity of material sprayed increases. Increasing the density of the deposit allows to reduce the presence of defects (porosity, cracks, etc.) and therefore increases the mechanical strength properties and/or the electrical and thermal properties of the deposit. A sandblasting step using alumina powder with a large particle size, for example 250 microns, may also be provided before the powder is sprayed to manufacture the resistive element ER, in order to increase the roughness of the substrate and consequently the mechanical bonding of the resistive element ER to the substrate SBT configured to form the electrodes PEL, DEL.

Alternatively, still within the scope of the applications covered by the invention, a powder with a particle size of between 15 and 45 μm may be produced by operating at high pressure, i.e. between 10 and 60 bar. The associated temperatures may then be between 400 and 600° C.

Generally speaking, and still in the context of the applications covered by the invention, a “Cold Spray” type method may therefore be used with a pressure ranging from 4 to 60 bar (low pressure ranging from 4 to 10 bar or high pressure ranging from 10 to 60 bar), with temperatures that may cover a wide range from 20° C. to 1000° C., depending in particular on the nature of the material forming the powder (listed above) and its particle size (which may range from 5 to 65 μm), with a carrier gas such as air, Argon or Helium.

Additive manufacturing techniques other than “Cold Spray” may be used. The resistive element ER may be additively manufactured using a technique referred to as “Direct Energy Deposition” (DED) and/or a technique referred to as “Laser Powder Bed Fusion” (LPPL) which, like the “Cold Spray” technique, allow the composition of the deposit to be controlled and varied during manufacture.

There are several possible strategies for obtaining the resistive element ER:
Deposition of the resistive alloy (Cold Spray, DED, FLPL): the composition and the properties are fixed,
Combinatorial deposition with direct fusion (DED, FLPL), used to create a custom alloy with refusals of alloy precursors (e.g.: Cu, Mn, Ni, Sn, Fe, Si),
Combinatorial deposition with localized post-processing (“Cold Spray” +post-processing by friction or laser): allows to obtain a deposit containing all the alloy precursors and to apply post-processing to obtain the desired electrical properties in a localized manner.

In this way, the composition and the composition gradients of the resistive elements are determined as a function of the electrical properties targeted, without being restricted to the strict (commercial) alloys generally used.

The result of step c) is an assembly as shown in FIG. 5c.

The annealing carried out in step d) may aim to restore the mechanical and electrical properties of the materials or to relieve the mechanical stresses and increase the strength of the deposit. Depending on the case, the annealing conditions are not the same. For example, annealing may be performed at a temperature of between 150 and 300° C. for between 15 and 60 minutes to restore the mechanical and electrical properties of the materials (restoration annealing). Annealing may also be performed at a temperature of around 300° C. for a period of one 1 or more, to relieve the mechanical stresses (recrystallisation annealing) and increase the strength of the deposit. Annealing may be carried out in air or in a controlled atmosphere. Typically, for the copper materials (such as manganin), annealing may be carried out in air or in a controlled atmosphere, at high temperatures of up to 600° C. (recrystallisation annealing), or at lower temperatures of around 200° C. (restoration annealing), bearing in mind that the melting temperature of the material forming the substrate must also be taken into account (for example, for aluminum, the melting temperature is 660° C. but it may nevertheless start to flow under stress from 450° C.).

Once annealing has taken place, part of the substrate SBT is removed in step e) of the method according to the invention, leaving only the resistive element ER between the two areas Z1, Z2 of the substrate. Applied to the manufacture of the electrical shunt SHE shown in FIG. 2, this step consists more specifically in drilling through the assembly recovered after annealing. This eliminates the retaining rod TM, but also the connection area of the substrate SBT between these two areas. This also allows, incidentally, in accordance with step f) of the method according to the invention, to create the two connection terminals BCE1, BCE2 on the areas Z1, Z2 in order to define the electrodes PEL, DEL.

The assembly obtained at the end of step f) is shown in FIG. 5d.

In an additional step, it is advantageous to create measurement terminals BM1, BM2. This produces the electrical shunt shown in FIG. 2.

FIG. 6 shows various parameters allowing the electrical shunt SHE of FIG. 2 to be designed before the piercing step (step e) above of the method according to the invention) of the assembly obtained after annealing:
D is the outside diameter of the electrodes PEL and LED with 3.5 mm<D<50 mm;
d is the inside diameter of the electrodes PEL and LED, with 1.5 mm<d<20 mm and dₘₐₓ=D/1.75;
h is the thickness of the resistive element ER, with 1 mm<h<(D−d)/2;
A designates the angle of inclination given to the cavity with 1°<a<90°, preferably A such that 30°<A<60°; and
L is the length of the electrical shunt with 5 mm<L<100 mm.

The values are adapted to the application.

Geometries other than that shown in FIG. 2 may be achieved using the method described in this invention.

By way of an additional, non-limiting example, it is possible to manufacture a busbar-type electrical shunt SHE′ as shown in FIG. 6.

In the case in point, step a) starts with a solid substrate of parallelepiped shape, wherein a cavity of the desired shape may be formed in step b), for example by machining. Here too, we could proceed differently to obtain the substrate with its non-through cavity. Step c) then repeats what has been described above, as do steps d), e) and f), whatever variants are envisaged that are also applicable to this other geometry. At the end of step f), the electrical shunt SHE′ is defined with its electrodes PEL′, DEL′ thus provided with connection terminals BCE1′, BCE2′, the electrodes being connected to each other by the single resistive element ER′. Advantageously, measurement terminals BM1′, BM2′ are also produced, as may be seen in FIG. 6.

The electrical shunt SHE, SHE′ obtained in the context of the invention may be used in particular to measure the electrical consumption or the state of charge of batteries in the following fields: transport (cars, aeronautics, railways, aerospace), metrology, industry and construction. This electrical shunt is more generally used to form any probe for measuring alternating current (AC) or direct current (DC) for electronics (10 to 500 A).

### Example of Embodiment: Manufacturing a Hollow Cylindrical Electrical Shunt

Firstly, a solid, cylindrical aluminum substrate SBT is provided (FIG. 5a), in accordance with step a) of the method according to the invention.

The substrate is then machined to define a non-through cavity CVT, in accordance with step b) of the method confirmed by the invention, in this case trapezoidal in cross-section, around the entire periphery of the substrate. In addition, one of the ends of the substrate is also machined to define a retaining rod TM useful for handling it during the manufacturing method (FIG. 5b). Apart from the retaining rod TM, the areas Z1, Z2 of the substrate on either side of the cavity CVT are those configured to form the first and the second electrodes. These areas Z1, Z2 are joined together by a portion POR of substrate, in this case cylindrical in shape, configured to disappear after the manufacturing method.

The resistive element ER is then additively manufactured in the cavity CVT, in accordance with step c) of the method according to the invention.

The additive manufacturing method used is the method referred to as “Cold Spray”, of the LPCS (low pressure) type. The starting point is a powder mixture (compatible with the “Cold Spray” method) of manganin with a particle size of 5 to 50 μm and alumina with a particle size of 5 to 25 μm, with alumina representing 20% by weight of the powder mixture. The method is implemented at a pressure of 8 bar and a temperature of 400° C., in air. The substrate is rotated continuously at 60 rpm at a speed of 30 mm/min. The coating is deposited in several successive layers, and each layer is deposited in the form of helices. The cold spray additive manufacturing operation is used to sandblast the surface of the substrate, in this case with 250 micron alumina powder. The sandblasting promotes the adhesion of the deposit performed during additive manufacturing by “Cold Spray” and therefore ultimately the mechanical strength of the resistive element on the substrate, in other words on the electrodes (FIG. 5c).

With additive manufacturing, the resistive element ER is dimensioned to obtain a defined value of its resistivity. This eliminates the need for a subsequent machining step (re-machining) to adapt the resistive element.

The assembly obtained at this stage of manufacture is then annealed, in accordance with step d) of the method according to the invention. This annealing is used to restore the mechanical and electrical properties of the various materials. In this case, it is a 1 hour annealing at 300° C.

Then, in accordance with step e) of the method according to the invention, a part of the substrate SBT is removed to leave only the resistive element ER between the two areas Z1, Z2 of the substrate. In practice, the substrate is pierced right through along its longitudinal axis AL. This operation removes the portion POR of the substrate that connected the two areas Z1 and Z2. This produces the desired hollow cylindrical shape.

In this case, piercing the substrate through and through allows step f) to be carried out at the same time in accordance with the method described in the invention. This allows the connection terminals to be generated at the end of each of the areas Z1, Z2 to finally form the first electrode and the second electrode. In this example, the retaining rod TM is also removed by the same operation.

The electrodes PEL, DEL and the resistive element ER are now defined, as are the electrical connection terminals BCE1, BCE2 (FIG. 5d).

Advantageously, measurement terminals BM1, BM2 may then be created. To create these measurement terminals, a tapped hole may be drilled and a pod screwed into it. A hole, for example a conical one, may also be made to accommodate a spring-mounted contactor. End of the example.

1. A method for manufacturing an electric current sensor (SHE) comprising the following steps:
a) providing a metal or metal alloy substrate (SBT),
b) making a non-through cavity (CVT) in said substrate so that said cavity separates the substrate into two areas (Z1, Z2),
c) producing a resistive element (ER) in said cavity (CVT) by additive manufacturing,
d) annealing the resulting assembly,
e) removing a part of the substrate (SBT) to leave only the resistive element (ER) between the two areas (Z1, Z2) of the substrate, and
f) defining, within each area (Z1, Z2), a connection terminal (BCE1, BCE2) to obtain electrodes (PEL, DEL).

2. The method for manufacturing an electrical current sensor according to claim 1, wherein the substrate provided in step a) is made of Aluminum, Copper or a Copper-based alloy.

3. The method for manufacturing an electric current sensor according to claim 1, wherein the cavity (CVT) produced in step b) is obtained by machining the substrate (SBT).

4. The method for manufacturing an electric current sensor according to claim 1, wherein step c) is carried out by cold spraying, advantageously at a pressure of less than 15 bar.

5. The method for manufacturing an electric current sensor according to claim 1, wherein step d) is performed at a temperature of between 400 and 600° C. for a period of between 5 and 15 minutes.

6. The method for manufacturing an electrical current sensor according to claim 1, comprising an additional step consisting in making a measurement terminal (BM1, BM2) in each of the two electrodes (PEL, DEL).

7. The method for manufacturing an electric current sensor according to claim 1, wherein the resistive element (ER) does not undergo any machining step, in particular to adapt the value of its resistivity.

8. The method for manufacturing an electrical current sensor according to claim 1, wherein the substrate (SBT) provided in step a) is a solid cylinder.

9. The method for manufacturing an electrical current sensor according to claim 1, wherein the substrate(S) provided in step a) is a solid parallelepiped.

10. The method for manufacturing an electrical current sensor according to claim 1, wherein said sensor is an electrical shunt.
